(19) United States
(12) Patent Application Publication
(10) Pub. No.: US 2026/0072342 A1
(43) Pub. Date: Mar. 12, 2026

(54) PHOTOMASK, METHOD OF FABRICATING THE PHOTOMASK AND METHOD OF MANUFACTURING DISPLAY DEVICE

(71) Applicant: Samsung Display Co., LTD., Yongin-si (KR)

(72) Inventors: Ju O NAM, Yongin-si (KR); Hyun Ju KANG, Yongin-si (KR)

(21) Appl. No.: 19/097,622

(22) Filed: Apr. 1, 2025

(30) Foreign Application Priority Data
Sep. 12, 2024 (KR) 10-2024-0124764

(51) Int. Cl. G03F 1/44; G03F 1/42; G03F 7/00; H10K 71/00

(52) U.S. Cl. CPC G03F 1/44; G03F 1/42; G03F 7/0007; G03F 7/70516; H10K 71/00

(57) ABSTRACT

A photomask has scan regions irradiated with unit beam areas in a scan direction, and an overlapping region including portions of adjacent scan regions included among the scan regions. The adjacent scan regions are adjacent in a sweeping direction of the scan regions. The sweeping direction is perpendicular to the scan direction of the scan regions. The photomask includes a monitoring mask pattern that overlaps the overlapping region or is adjacent to a boundary of the overlapping region, and the monitoring mask pattern includes a side having an oblique line shape inclined with respect to the sweeping direction.

This application claims priority to Korean Patent Application No. 10-2024-0124764, filed on Sep. 12, 2024, and all the benefits accruing therefrom under 35 U.S.C. § 119, the content of which in its entirety is herein incorporated by reference.

### FIELD

Embodiments of the present application relate to a photomask, a method of fabricating the photomask, and a method for manufacturing a display device. More specifically, embodiments of the present application relate to a photomask capable of being used in a photo-lithography process, a method for fabricating the photomask, and a method for manufacturing a display device.

### BACKGROUND

In a display device such as, for example, an organic light emitting diode (OLED) display and a liquid display device (LCDs), thin film transistors (TFTs) and various wirings are formed by a photo-lithography process, and pixel areas can also be formed by the photo-lithography process.

A photo-lithography process includes performing an exposure process. For example, an exposure apparatus may be aligned with a mask pattern to irradiate an object with light. Accordingly, a desired pattern image may be transferred to an etching object. The exposure apparatus may also be used in an exposure process for fabricating a photomask.

For example, in the exposure process, a laser beam such as, for example, an excimer laser, an EUV laser, or a semiconductor laser may be divided into a plurality of unit laser beams to perform a scanning. An accuracy of the photo-lithography process may be degraded due to distortion of a scanning movement direction, non-uniformity in a size of the unit laser beam, a mis-alignment, or the like.

### SUMMARY

According to an aspect of the present disclosure, there is provided a photomask providing enhanced accuracy and reliability.

According to an aspect of the present disclosure, there is provided a method of fabricating a photomask providing enhanced accuracy and reliability.

According to an aspect of the present disclosure, there is provided a method of a manufacturing a display device using the photomask.

A photomask may have scan regions irradiated with unit beam areas in a scan direction, and an overlapping region including portions of adjacent scan regions included among the scan regions, wherein the adjacent scan regions are adjacent in a sweeping direction of the scan regions and at least partially overlap. The sweeping direction is perpendicular to the scan direction. The photomask may include a monitoring mask pattern that overlaps the overlapping region or is adjacent to a boundary of the overlapping region. The monitoring mask pattern may include a side having an oblique line shape inclined with respect to the sweeping direction.

In some embodiments, the monitoring mask pattern may be provided in plurality, and the plurality of the monitoring mask patterns may be arranged over the overlapping region in an inclined direction with respect to the scan direction.

In some embodiments, the monitoring mask pattern may include a first monitoring mask pattern that is completely included within the overlapping region.

In some embodiments, the monitoring mask pattern may further include a second monitoring mask pattern that overlaps an initiation line of the overlapping region or a third monitoring mask pattern that overlaps a terminal line of the overlapping region.

In some embodiments, the monitoring mask pattern may further include a fourth monitoring mask pattern adjacent to an initiation line or a terminal line of the overlapping region, and the fourth monitoring mask pattern may not be included in the overlapping region.

In some embodiments, the monitoring mask pattern may have a sloped angle with respect to the sweeping direction, the monitoring mask pattern may be provided in plurality, and respective sloped angles of the plurality of monitoring mask patterns may be different from one another.

In some embodiments, the sloped angle may be adjusted in a range from 10° to 80°.

In some embodiments, the monitoring mask pattern may be provided in plurality, and the plurality of monitoring mask patterns may have different respective sizes.

In some embodiments, the monitoring mask pattern may be provided in plurality, and the plurality of monitoring mask patterns may include rhombus patterns having different ratios of lengths of two diagonal lines.

In some embodiments, the plurality of monitoring mask patterns may further include a rectangular pattern sloped with respect to the sweeping direction.

In some embodiments, the photomask may have a main area including a main mask pattern, a peripheral area at least partially surrounding the main area, and a monitoring mark area allocated in the peripheral area. The monitoring mask pattern may be included in the monitoring mark area.

In some embodiments, the photomask may include a transmissive layer, and a mask pattern layer formed on the transmissive layer. The mask pattern layer may include the monitoring mask pattern and the main mask pattern.

In some embodiments, the overlapping region may be included in the monitoring mark area and the main area, and the main mask pattern may include a pattern including a side having an oblique line shape inclined with respect to the sweeping direction in the overlapping region.

In some embodiments, a width of the overlapping region in the sweeping direction may range from 5 μm to 15 μm, and a size of the monitoring mask pattern may be less than a size of the overlapping region.

A method of fabricating a photomask includes forming a monitoring mask pattern by performing a preliminary exposure process, wherein the monitoring mask pattern includes a side having an oblique line shape with respect to a sweeping direction, and the preliminary exposure process is performed such that adjacent scan regions extending in a scan direction share an overlapping region in a sweeping direction perpendicular to the scan direction. The method includes comparing a size or a shape of the monitoring mask pattern with a size or a shape of a desired target mask pattern. The method includes modifying exposure conditions based on a comparison result. The method includes forming a main mask pattern using the modified exposure conditions.

In some embodiments, the main mask pattern may include a pattern including a side having an oblique line shape inclined with respect to the sweeping direction, and the pattern is formed in the overlapping region by an exposure process. In some embodiments, the monitoring mask pattern may be formed in monitoring mark areas, and the main mask pattern may be formed in a main area. The modification of the exposure conditions may be performed repeatedly in multiple cycles based on comparison results in different monitoring mark areas before forming the main mask pattern.

A method for manufacturing a display device includes preparing a display panel including a base substrate, a circuit layer on the base substrate, pixel electrodes electrically connected to the circuit layer and a pixel defining layer covering the pixel electrodes. The method includes forming pixel areas that expose the pixel electrodes by pattering a pixel defining layer using a photomask described herein.

In some embodiments, the method may include forming the photomask by a modified exposure process using the monitoring mask pattern. The photomask may include main mask patterns, and each of the main mask patterns may include a side having an oblique line shape inclined with respect to the sweeping direction.

In some embodiments, the pixel areas may include a pixel area formed from an exposure process using a main mask pattern arranged in the overlapping region among the main mask patterns.

A photomask according to embodiments of the present invention may include a monitoring mask pattern which may be formed in a monitoring mark area and may include a side of a diagonal line shape with respect to a sweeping direction. Patterning errors and deviations occurring in an overlapping region of scan regions may be measured using the monitoring mask pattern, and the measurement results may be reflected in exposure conditions. A main mask pattern having improved precision and reliability may be formed in a main area using the adjusted exposure conditions.

A patterning process of forming an oblique or diagonal line pattern such as, for example, a pixel region patterning of a display device may be performed with high reliability and high precision by using the photomask.

### BRIEF DESCRIPTION OF THE DRAWINGS

FIG. 1 is a schematic diagram illustrating an exposure apparatus according to embodiments.

FIGS. 2 and 3 are schematic plan views for describing light irradiation using an exposure apparatus according to embodiments.

FIG. 4 is a graph illustrating a light intensity profile for describing a light irradiation using an exposure apparatus according to embodiments.

FIGS. 5 and 6 are schematic plan views for describing light irradiation deviation in an overlapping region of adjacent sweeping regions.

FIG. 7 is a schematic plan view illustrating a photomask according to embodiments.

FIGS. 8 to 11 are partial enlarged plan views schematically illustrating an arrangement of monitoring mask patterns in an overlapping region of a photomask according to embodiments.

FIG. 12 is a process flowchart illustrating a method of fabricating a photomask according to embodiments.

FIGS. 13 and 14 are schematic cross-sectional views for describing a method of manufacturing a display device according to embodiments.

FIG. 15 is a schematic partial enlarged plan view illustrating a pixel area of a display device according to embodiments.

### DETAILED DESCRIPTION

Hereinafter, embodiments of the present invention will be described in more detail with reference to the attached drawings. The same reference numerals can l be used for indicating the same elements in the drawings, and repeated descriptions of the same elements can be omitted. Embodiments disclosed in the attached drawings are examples, and is to be understood to include all modifications, equivalents and substitutes included in the spirit and technical scope of the present invention.

The terms “on”, “connected”, “coupled,” and the like used herein refers to a direct placement/connection/combination, and also refers to a case where another element is interposed two different elements.

The terms “first”, “second”, “below”, “below”, “above,” “above,” and the like are used in a relative sense to distinguish different elements or positions, and do not specify an absolute position or an absolute order.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular. The term “substantially zero” means approximately or actually zero.

Spatially relative terms, such as, for example, “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

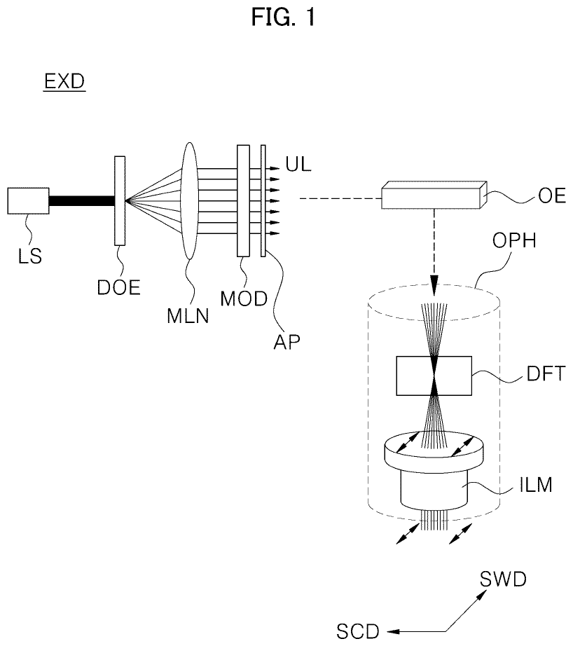

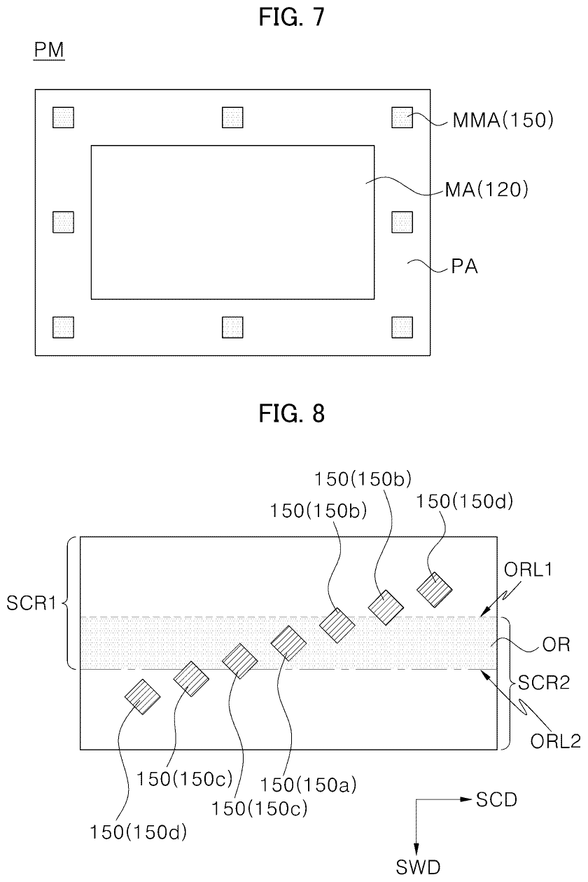

FIG. 1 is a schematic diagram illustrating an exposure apparatus according to embodiments. The exposure apparatus may be an exposure equipment that exposes a pattern layer or a light-shielding layer of a photomask PM (see FIG. 7) to form a pattern on the photomask PM (see FIG. 7).

Referring to FIG. 1, an exposure apparatus EXD may include a light source LS, a diffractive optical element DOE, a module lens MLN, a modulator MOD, an aperture AP, an optical element OE, and an optical head OPH.

The light source LS may include a laser oscillator. For example, the light source LS may include an excimer laser oscillator using KrF, ArF, XeCl, or the like; a gas laser oscillator using He, He-Cd, Ar, He-Ne, HF, or the like; a solid-state laser oscillator using YAG, YAlO₃, Y₂O₃, YVO₄, GdVO₄, or the like; a semiconductor laser oscillator using GaN, GaAs, GaAlAs, InGaAsP, or the like.

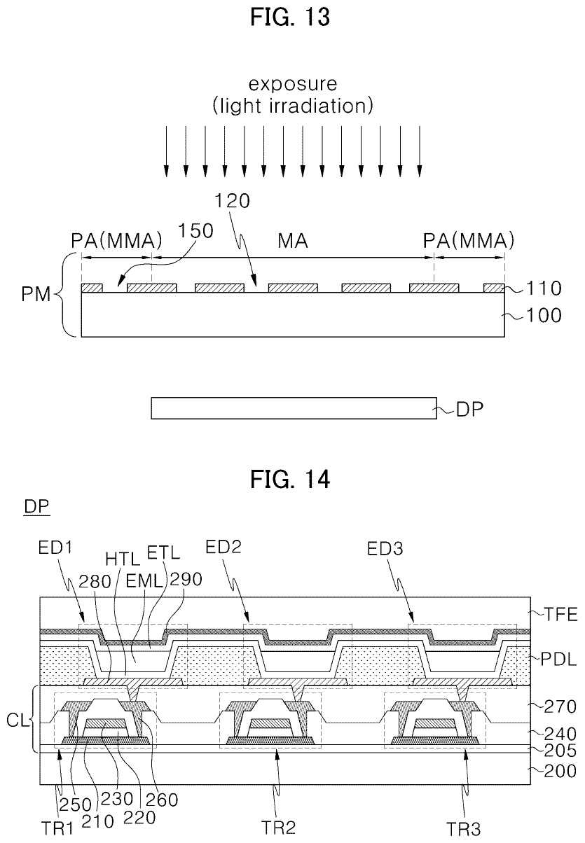

A laser having an energy capable of being absorbed by a mask pattern layer 110 (see FIG. 13) may be selected. For example, a laser in an extreme ultraviolet region, a laser in an ultraviolet region, a laser in a visible light region, and/or a laser in an infrared region may be appropriately selected in consideration of a target pattern.

A continuous oscillation laser beam or a pulsed oscillation laser beam may be emitted from the light source LS. A raw bulk laser emitted from the light source LS may be divided into a plurality of unit laser beams UL by the diffractive optical element DOE.

The module lens MLN may be disposed between the diffractive optical element DOE and the modulator MOD. The module lens MLN may focus each unit laser beam UL on the modulator MOD. The modulator MOD may change an intensity and/or an irradiation duration of the focused unit laser beam UL. The modulator MOD may include, e.g., an acousto optical modulator (AOM). The irradiation duration may refer to an amount of time which the focused unit laser beam UL irradiates a target object or target region.

The intensity and/or the irradiation duration of the unit laser beam UL may be adjusted in each of channels included in the modulator MOD. The aperture AP may adjust an amount and an emission direction of a plurality of the unit laser beams UL. The aperture AP may have a slit shape.

The optical element OE may be disposed on an optical path between the aperture AP and the optical head OPH. The optical element OE may change an optical path such that a plurality of the unit laser beams UL emitted from the aperture AP may be incident to the optical head OPH.

The optical head OPH may serve as an optical scanning device and may reciprocate along a scan direction SCD. A light scanning may be performed while the optical head OPH moves along the scan direction SCD. The light scanning may be repeated by being shifted along a sweeping direction SWD.

The optical head OPH may include a deflector DFT and an irradiation lens ILN. The deflector DFT may deflect and sweep the unit laser beams UL onto the photomask PM. The deflector DFT may include an acousto optical deflector AOD. The irradiation lens ILN may focus a plurality of the unit laser beams UL on the photomask PM.

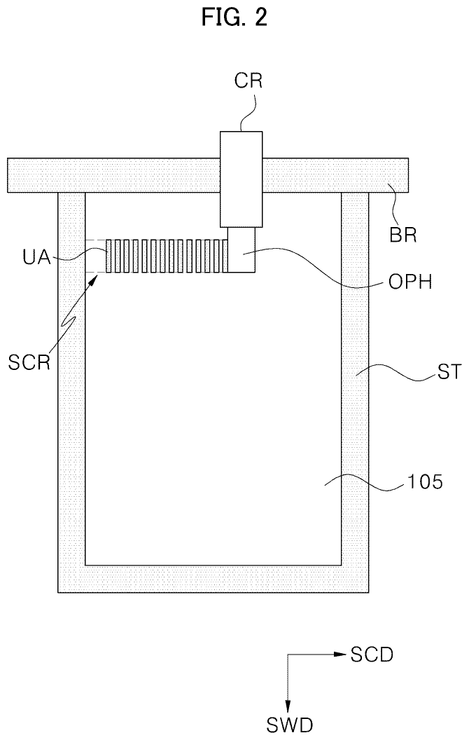

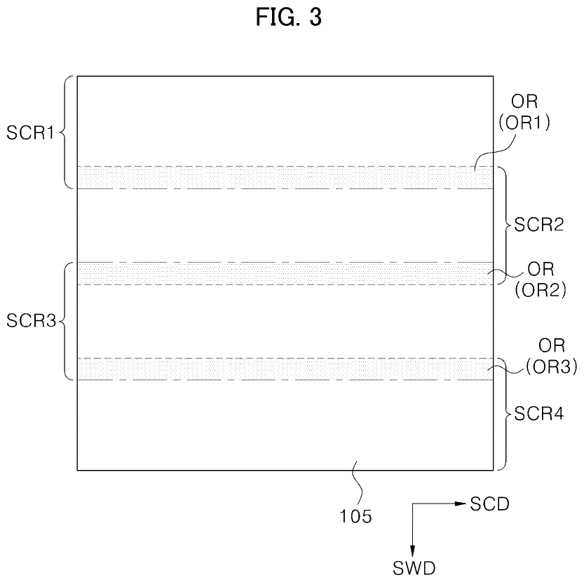

FIGS. 2 and 3 are schematic plan views for describing light irradiation using an exposure apparatus according to embodiments.

Referring to FIG. 2, the optical head OPH may be coupled to a carrier CR and may move in the scan direction SCD along a bridge BR, and an optical scan may be performed on a mask layer 105 for forming the mask pattern layer 110 of the photomask. During the optical scan, a unit beam area UA corresponding to the unit laser beam UL may be formed from the optical head OPH. While a plurality of the unit beam areas UA are generated in the scan direction SCD, a scan region SCR may be formed.

As described herein, the bridge BR supporting the movement of the optical head OPH in a horizontal direction (the scan direction SCR) may move along the sweeping direction SWD by a sweep unit on a stage ST. Accordingly, the scan region SCR may be generated through the optical scanning for each sweep unit.

The scan region SCR and the sweeping direction SWD may be parallel to a top surface of the mask layer 105 and may be perpendicular to each other.

Referring to FIG. 3, as described herein, the unit beam areas UA may be continuously generated from the optical head OPH of the exposure apparatus EXD to form the scan region SCR.

According to embodiments, a first scan region SCR1 may be defined while the optical head OPH moves from one side of the mask layer 105 to the other side of the mask layer along the scan direction SCD. After returning to the one side of the mask layer 105, the optical head OPH may be moved in a predetermined sweep unit or a sweep distance in the sweeping direction SWD. Thereafter, the optical head OPH may move back to the other side of the mask layer 105 to perform an optical scan, and a second scan region SCR2 may be defined.

The described optical scan/sweep may be repeated, such that a third scan region SCR3 and a fourth scan region SCR4 may be sequentially defined. The optical scan/sweep and may be repeated until an nth scan region (n is a natural number of 5 or more) is generated.

According to embodiments, the scan regions SCR adjacent to each other in the sweeping direction SWD may partially overlap each other. Accordingly, the adjacent scan regions SCR may be repeated along the sweeping direction SWP while sharing an overlapping region OR (shaded in FIG. 3 and the following drawings).

The term “adjacent” herein may refer to elements which are relatively close to each other (e.g., within a target distance). In some other cases, the term “adjacent’ herein may refer to elements which are in contact with each other and/or at least partially overlapping. In some cases, the term “adjacent” herein may refer to elements of the same type, in which another element of the same type is not disposed between the elements. For example, for a scan region SCR (e.g., first scan region SCR1) described as adjacent to another scan region SCR (e.g., second scan region SCR2), another scan region SCR is not present between the adjacent scan regions SCR.

For example, as illustrated in FIG. 3, the first scan region SCR1 and the second scan region SCR2 may be adjacent while sharing a first overlapping region OR1. The second scan region SCR2 and the third scan region SCR3 may be adjacent while sharing a second overlapping region OR2. The third scan region SCR3 and the fourth scan region SCR4 may be adjacent while sharing a third overlapping region OR3.

As described herein, the sweeping may be performed such that the scan regions SCR adjacent to each other in the sweeping direction SWD may share the overlapping region OR. Accordingly, for example, the sweeping may prevent or reduce discontinuous irradiation of target regions due to an alignment error of the optical head OPH. For example, generation of a discontinuous region of a light irradiation due to an alignment error of the optical head OPH may be prevented, and defects such as, for example, a pattern breakage may be suppressed.

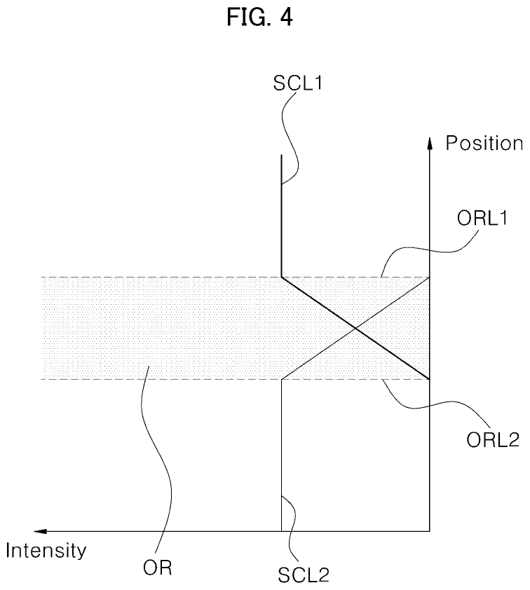

FIG. 4 is a graph illustrating a light intensity profile for describing light irradiation using an exposure apparatus according to embodiments. In the graph of FIG. 4, the Y axis represents a position of the light irradiation or the unit beam area UA (i.e., a position at which a laser is irradiating a target) and the X axis represents a light intensity.

Referring to FIG. 4, e.g., a light intensity of a first scan laser SCL1 in the first scan region SCR1 of FIG. 3 may gradually decrease from an initiation line ORL1 to a terminal line ORL2 of the overlapping region OR. The light intensity of the first scan laser SCL1 may be substantially zero at the terminal line ORL2. For example, the light intensity of the first scan laser SCL1 may be weakened in a linear shape.

A light intensity of the second scan laser SCL2 in the second scan region SCR2 of FIG. 3 may gradually increase from the initiation line ORL1 to the terminal line ORL2 of the overlapping region OR. The light intensity of the second scan laser SCL2 may be substantially zero at the initiation line ORL1. For example, the light intensity of the second scan laser SCL2 may increase in a linear shape and may have a maximum value at the terminal line ORL2.

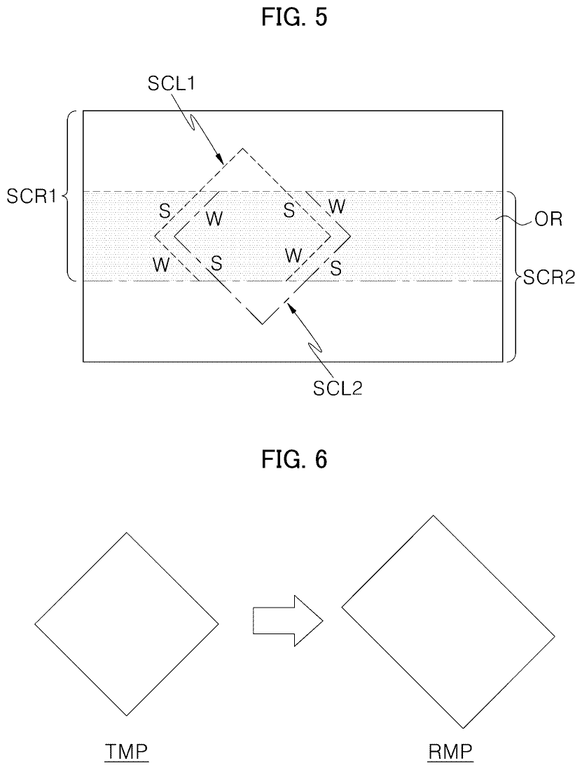

FIGS. 5 and 6 are schematic plan views for describing light irradiation deviation in an overlapping region of adjacent (i.e., neighboring) sweeping regions.

Referring to FIG. 5, as described with reference to FIG. 4, the light intensities of the first scan laser SCL1 and the second scan laser SCL2 may be changed in the overlapping region OR such that increase and decrease of the light intensities may be opposite to each other.

Accordingly, as illustrated in FIG. 5, when a mask pattern including sides having an oblique or diagonal line shape is formed in an exposure mask, a relatively strong laser line S and a relatively weak laser line L may be mixed and distributed in the overlapping region OR with respect to an intersection of the light intensities of the first scan laser SCL1 and the second scan laser SCL2. For example, the strong laser line S of the first scan laser SCL1 and the weak laser line W of the second scan laser line SLC2, and the weak laser line W of the first scan laser SCL1 and the strong laser line S of the second scan laser line SLC2 may be adjacent to each other around a profile of a desired mask pattern.

Thus, as illustrated in FIG. 6, an actual mask pattern RMP having a shape modified from a desired diamond-shape target mask pattern TMP may be generated along the strong laser lines S.

As described herein, when the desired target mask pattern TMP includes a shape such as, for example, a rhombus shape that may have a side having an oblique line shape, the actual mask pattern RMP may have a deformed shape including a patterning error from the desired rhombus shape. Accordingly, a device pattern formed using the actual mask pattern RMP may also be deformed from a desired shape.

Further, if the linear light intensity change profile as illustrated in FIG. 4 is deformed (e.g., in a curved shape) due to an error in the exposure apparatus EXD or the optical head OPH, a degree of deformation of the actual mask pattern RMP may be further increased.

FIG. 7 is a schematic plan view illustrating a photomask according to embodiments.

Referring to FIG. 7, the photomask PM according to embodiments may include a main area MA and a peripheral area PA.

A main mask pattern 120 (see FIG. 13) for forming a desired target device pattern may be formed in the main area MA. The main area MA includes a central area of the photo mask PM. The peripheral area PA may be allocated along a boundary or an outer periphery of the main area MA, and may at least partially surround the outer periphery of the main area MA.

The main mask pattern 120 may include a side having an oblique line shape inclined with respect to the sweeping direction SWD such as, for example, a side of a rhombus shape. The main mask pattern 120 may be formed by an exposure process in the scan regions SCR as described herein, and may include a pattern formed in the overlapping region OR.

In example embodiments, the peripheral area PA may include a monitoring mark area MMA. In some embodiments, a plurality of the monitoring mark areas MMA may be spaced apart by a specific distance and arranged in the peripheral area PA.

For example, as illustrated in FIG. 7, the monitoring mark areas MMA may be adjacent to both lateral portions, corner portions, an upper portion and/or a lower portion of the main area MA.

A monitoring mask pattern 150 (see FIG. 13) may be included in the monitoring mark area MMA.

FIGS. 8 to 11 are partial enlarged plan views schematically illustrating an arrangement of monitoring mask patterns in an overlapping region of a photomask according to embodiments. For example, FIGS. 8 to 11 illustrate the arrangement of the monitoring mask patterns 150 in the monitoring mark area MMA illustrated in FIG. 7.

Areas illustrated in FIGS. 8 to 11 may be a partial area of the monitoring mark area MMA.

Referring to FIG. 8, the overlapping region OR in which adjacent scan regions SCR1 and SCR2 overlap each other may also be included in the monitoring mark area MMA. The monitoring mask pattern 150 may be formed on the overlapping region OR.

In example embodiments, the monitoring mask pattern 150 may include a side having an oblique line shape inclined with respect to the sweeping direction SWD. In some embodiments, the monitoring mask pattern 150 may have a substantially rhombus shape.

In some embodiments, a plurality of the monitoring mask patterns 150 may be formed over the overlapping region OR along the scan direction SCD. In an embodiment, a plurality of the monitoring mask patterns 150 may be formed over the overlapping region OR in a diagonal direction inclined at a specific angle with respect to the scan direction SCD.

The monitoring mask pattern 150 may have a size such that the monitoring mask pattern 150 is completely included in the overlapping region OR. In some embodiments, a width (a width in the sweeping direction SWD) of the overlapping region OR may range from 5 μm to 15 μm, from 7 μm to 12 μm, from 8 μm to 11 μm, from 8.5 μm to 10.5 μm.

A length of a long axis of the monitoring mask pattern 150 (a length of a long diagonal line among diagonal lines) may be smaller than the width of the overlapping region OR. Accordingly, an error/deformation generated when forming a pattern including the oblique or diagonal line as described with reference to FIGS. 5 and 6 in the overlapping region OR may be effectively identified and corrected from the monitoring mask pattern 150.

The monitoring mask pattern 150 may be provided in plurality. The monitoring mask pattern 150 may include a first monitoring mask pattern 150a completely included in the overlapping region OR. In some embodiments, the monitoring mask patterns 150 may include monitoring mask patterns 150b and monitoring mask patterns 150c that may be partially included in the overlapping region OR. The monitoring mask pattern 150 may further include a second monitoring mask pattern 150 (e.g., monitoring mask pattern 150b) overlapping the initiation line ORL1 of the overlapping region OR and a third monitoring mask pattern 150 (e.g., monitoring mask pattern 150c) overlapping the terminal line ORL2 of the overlapping region OR.

In some embodiments, the monitoring mask pattern 150 may further include a fourth monitoring mask pattern 150d which is adjacent to the overlapping region OR and does not overlap the overlapping region OR. The fourth monitoring mask pattern 150d may be commonly formed in a non-overlapping region adjacent to the initiation line ORL1 and a non-overlapping region adjacent to the terminal line ORL2.

As described herein, the monitoring mask patterns 150 may be distributed throughout the overlapping region OR and the non-overlapping region, such that pattern formation errors/defects in the overlapping region OR and the adjacent region may be confirmed or detected with high probability and reliability.

In some aspects, an arrangement direction of the monitoring mask patterns 150 may also be sloped, tilted or inclined with respect to the scan direction SCD, thereby further increasing a possibility of detection of patterning errors caused by or related to oblique lines. That is, for example, sloping or inclining the arrangement direction of the monitoring mask patterns 150 with respect to the scan direction SCD may support increased detection of patterning errors caused by or related to oblique lines.

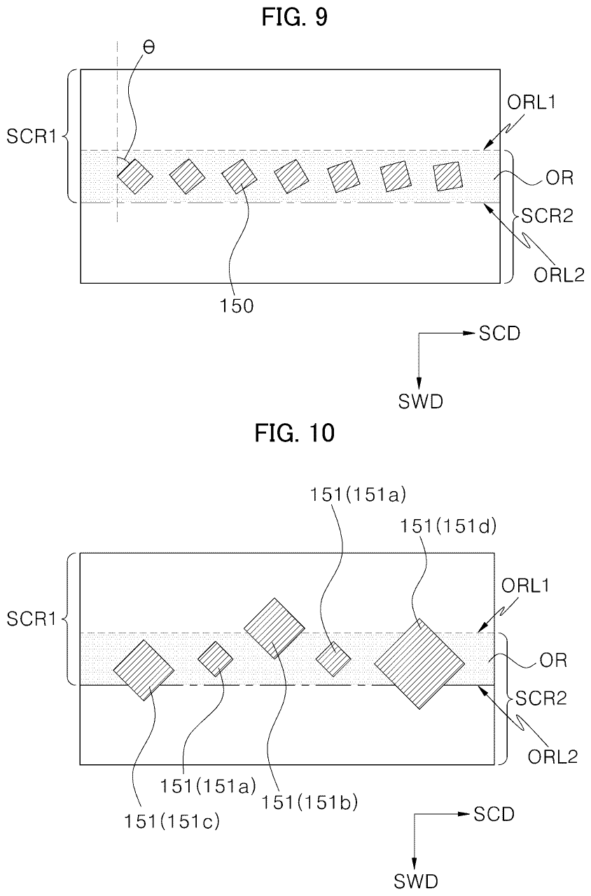

Referring to FIG. 9, an orientation of a plurality of the monitoring mask patterns 150 may be changed on the overlapping region OR. For example, the monitoring mask patterns 150 may be formed while changing sloped angles θ (also referred to herein as tilting angles) between the sweeping direction SWD and one side of the diamond-shaped monitoring mask pattern 150. Expressed another way, respective sloped angles of the monitoring mask patterns 150 may be different from one another.

In some embodiments, as illustrated in FIG. 9, the monitoring mask patterns 150 may be distributed while sequentially changing the sloped angle θ in a clockwise direction along the scan direction SCD. Alternatively, the monitoring mask patterns 150 may be distributed while sequentially changing the sloped angle θ in a counterclockwise direction. For example, embodiments of the present disclosure may include arranging or distributing the monitoring mask patterns 150 such that, among the monitoring mask patterns 150, a subsequent monitoring mask pattern 150 (e.g., the monitoring mask pattern 150 second from the left in FIG. 9) is rotated in a clockwise direction compared to a prior monitoring mask pattern 150 (e.g., the leftmost monitoring mask pattern 150 in FIG. 9). Expressed another way, among the monitoring mask patterns 150, the sloped angle θ of a subsequent monitoring mask pattern 150 is different from (e.g., greater than, but not limited to) the sloped angle θ of a prior monitoring mask pattern 150.

Accordingly, patterning errors occurring when forming oblique line patterns of various angles may be precisely detected and measured.

In some embodiments, the sloped angle θ may be adjusted in a range from 10° to 80°.

Referring to FIG. 10, the monitoring mask pattern 151 may be provided in plurality. For example, the monitoring mask pattern 151 may include patterns having different respective sizes.

In example embodiments, the monitoring mask patterns 151 may include a first monitoring mask pattern 151a having a size completely included in the overlapping region OR. Further, for example, the monitoring mask patterns 151 may include a second monitoring mask pattern 151b, a third monitoring mask pattern 151c, and/or a fourth monitoring mask pattern 151d having respective long axis lengths (e.g., in the scanning direction SCD) greater than the width (e.g., in the scanning direction SCD) of the overlapping region OR.

The second monitoring mask pattern 151b may include a protruding portion from the overlapping region OR to an outside of the initiation line ORL1 in a plan view. The third monitoring mask pattern 151c may include a protruding portion from the overlapping region OR to an outside of the terminal line ORL2 in the plan view. The fourth monitoring mask pattern 151d may include protruding portions from the overlapping region OR to the outside of each of the initiation line ORL1 and the terminal line ORL2.

As described herein, the size of the monitoring mask pattern 151 may be changed to easily analyze the degree of patterning errors occurring when the oblique line pattern is formed.

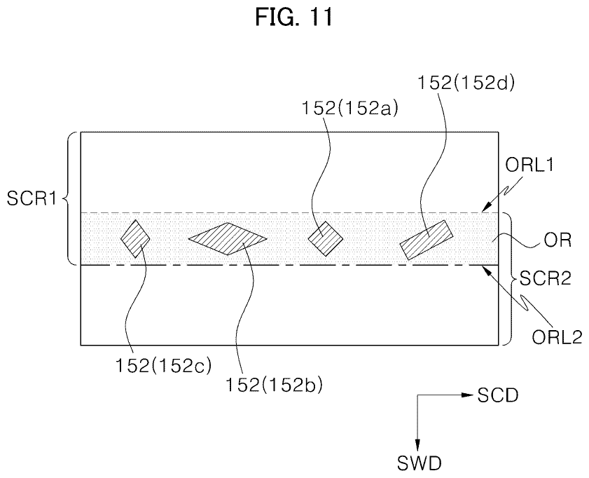

Referring to FIG. 11, the monitoring mask pattern 151 may be provided in plurality. For example, the monitoring mask pattern 152 may include patterns having different shapes. In some embodiments, the monitoring mask pattern 152 may include diamond patterns having different length ratios of two diagonal lines.

For example, the monitoring mask pattern 152 may include a first monitoring mask pattern 152a having the same length of two diagonal lines, a second monitoring mask pattern 152b having a length of a vertical diagonal line less than a length of a horizontal diagonal line, and/or a third monitoring mask pattern 152c having a length of a vertical diagonal line greater than a length of a horizontal diagonal line. The term “diagonal line” herein refers to a virtual line extending between vertices which are not directly connected in a polygon (e.g., a rhombus).

The monitoring mask pattern 152 may include a fourth monitoring mask pattern 152d having a rectangular shape sloped at a specific angle with respect to the sweeping direction SWD.

As described herein, embodiments of the present disclosure may include changing the orientation, the arrangement direction, the position, the size, the shape, or the like of the monitoring mask patterns 150, 151 and 152 overlapping the overlapping region OR or being adjacent to the overlapping region OR such that information such as, for example, a type, a degree, a position, a direction, or the like of the patterning errors occurring when forming the oblique line pattern may be comprehensively detected and measured.

In some aspects, for a set of monitoring mask patterns described herein (e.g., monitoring mask patterns 150 of FIG. 8, monitoring mask patterns 151 of FIG. 10, or the like), the monitoring mask patterns may differ from one another based on respective position, size, shape, orientation, or the like.

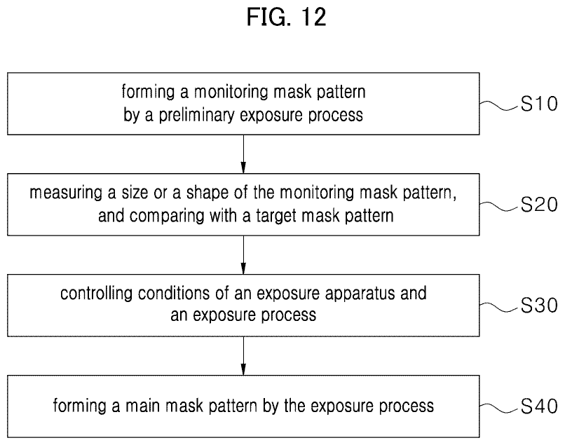

FIG. 12 is a process flowchart illustrating a method of fabricating a photomask according to embodiments.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 12, the method may include forming the monitoring mask patterns 150, 151, and 152 by a preliminary exposure process (e.g., an operation S10).

The preliminary exposure process may be performed in the monitoring mark area MMA of the peripheral area PA allocated to the photo mask PM (see FIG. 7). For example, the preliminary exposure process may be performed using the exposure mechanism described with reference to FIGS. 2 to 4 using the exposure apparatus EXD described with reference to FIG. 1.

In example embodiments, the method may include performing the preliminary exposure process such that the scanning regions SCR adjacent to each other in the sweeping direction SWD share a respective overlapping region OR. The monitoring mask patterns 150, 151 and 152 each including a side having an oblique line shape inclined at a specific angle with respect to the sweeping direction SWD may be formed by the preliminary exposure process.

In some embodiments, the method may include forming the monitoring mask patterns 150, 151 and 152 according to the orientation, the arrangement direction, the position, the size, the shape, or the like, as described with reference to FIGS. 8 to 11.

The method may include measuring the size or the shape of the formed monitoring mask patterns 150, 151 and 152. The method may include comparing the measured size with a size a desired target mask pattern and/or comparing the measured shape with a shape of the desired target mask pattern (e.g., an operation S20).

The method may include determining, based on the comparison result, occurrence of an abnormality in the exposure apparatus or exposure process conditions (exposure conditions) for the formation of the mask pattern including the side of the oblique line shape. That is, for example, the method may include determining whether an abnormality has occurred in the exposure apparatus or exposure process conditions (exposure conditions) for the formation of the mask pattern.

The method may include modifying the exposure conditions based on the comparison result (e.g., an operation S30).

For example, the exposure conditions may include a position, an alignment state, or the like, of the optical head OPH. The exposure conditions may include a size, an alignment state, or the like, of the unit laser beam UL and/or the unit beam area UA generated by the optical head OPH. The exposure conditions may include the intensity of the laser light generated by the optical head OPH. The exposure conditions may include the width of the overlapping region OR.

The method may include performing and exposure process for forming the main mask pattern by using the exposure conditions modified as described herein. The exposure process may be performed in the main area MA allocated to the photomask PM.

As described herein, the main mask pattern 120 may be formed under exposure conditions modified using the monitoring mask patterns 150, 151 and 152 (e.g., an operation S40). Thus, even for cases in which the main mask pattern 120 or the device pattern formed therefrom includes an oblique line, an error may be suppressed and a pattern having a desired shape may be created.

In some embodiments, the method may include repeatedly performing the processes S10 to S30 in a plurality of cycles. For example, after the monitoring mask pattern 150 is formed in one region of the monitoring mark regions MMA illustrated in FIG. 7, the method may include comparing a size/shape of the monitoring mask pattern with a target mask pattern. Thereafter, the method may include adjusting or maintaining exposure conditions based on the comparison result (a first monitoring).

After the monitoring mask pattern 150 is formed again in another region different from the one region of the monitoring mark regions MMA under the exposure condition adjusted by the first monitoring, the method may include comparing a size and/or a shape of the monitoring mask pattern 150 with a size and/or a shape of the target mask pattern. Thereafter, the method may include again adjusting or maintaining the exposure conditions based on the comparison result (a second monitoring).

As described herein, an accuracy of the main mask pattern 120 formed in the main area MA may be further enhanced by repeating monitoring.

FIGS. 13 and 14 are schematic cross-sectional views for describing a method of manufacturing a display device according to embodiments.

Referring to FIG. 13, the method may include preparing the photomask PM fabricated as described with reference to FIG. 12. The photomask PM may include a transmissive layer 100 and the mask pattern layer 110 formed on the transmissive layer 100.

The transmissive layer 100 may include a transparent material (e.g., quartz) that transmits a laser beam used for irradiating an object in an exposure process. The mask pattern layer 110 may include a material having a light-shielding property (e.g., a metal such as, for example, chromium). The mask pattern layer 110 may be formed by etching or patterning the mask layer 105 including the light-shielding material using the described exposure apparatus/exposure process.

As described herein, the photomask PM or the mask pattern layer 110 may include the main area MA and the monitoring mark area MMA. The main area MA and the monitoring mark area MMA may include the main mask pattern 120 and the monitoring mask pattern 150, respectively.

As described herein, the monitoring mask pattern 150 may include a pattern including a side having an oblique line shape which may be formed by the exposure process including the overlapping scanning regions SCR. The main mask pattern 120 may also include a pattern including a side having an oblique line shape which may be formed by the exposure process including the overlapping scanning regions SCR.

As illustrated in FIG. 13, the method may include providing the monitoring mask pattern 150 and the main mask pattern 120 as an opening or an engraved pattern formed by removing the mask layer 105 (e.g., through etching or patterning described herein).

Alternatively, the method may include providing the mask layer 105 as an embossed pattern in which the mask layer 105 remains. In this case, for example, the method may include removing portions of the mask layer around the monitoring mask pattern 150 and the main mask pattern 120.

After the main area MA of the photomask PM is aligned with a display panel DP, the method may include forming a device pattern included in the display panel DP by an exposure process. The exposure process may transfer an image of the main mask pattern 120 to the display panel DP. After the exposure process, the method may include forming the device pattern by an etching process including a development process.

Referring to FIG. 14, the display panel DP may include a base substrate 200, a circuit layer CL including transistors TR1, TR2 and TR3 arranged on the base substrate 200, and light-emitting devices connected to the transistors TR1, TR2, and TR3.

The method may include providing the base substrate 200 as a back-plane substrate of a display device or the display panel DP. The base substrate 200 may include a glass substrate, a ceramic substrate or a plastic substrate. In some embodiments, the base substrate 200 may include a polymer material having transparency and flexibility. In this case, for example, the base substrate 200 may be used in a transparent flexible, bendable or foldable display device.

For example, the base substrate 200 may include a polymer material such as, for example, polyimide, polysiloxane, an epoxy resin, an acrylic resin, polyester, polyarylate, polycarbonate, polyethersulfone, polyphenylene sulfide, or the like. In an embodiment, the base substrate 200 may include polyimide.

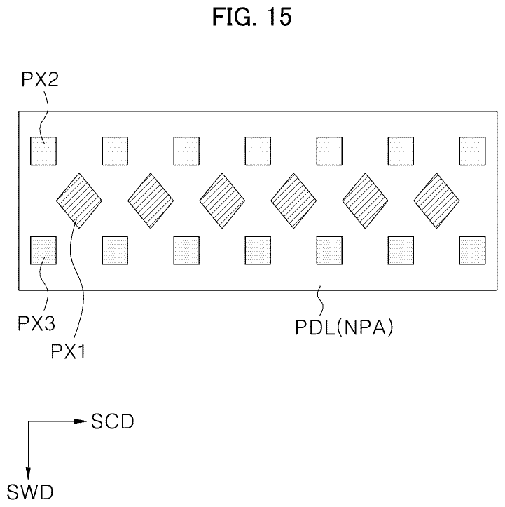

The method may include forming a buffer layer 205 on a top surface of the base substrate 200. Moisture penetrating through the base substrate 200 may be blocked by the buffer layer 205, and diffusion of impurities between the base substrate 200 and structures formed on the base substrate 200 may be blocked. The buffer layer 205 may be formed entirely over pixel areas (areas indicated by PX1, PX2 and PX3 of FIG. 15) and a non-pixel area NPA of the base substrate 200, and the buffer layer 205 may entirely cover the top surface of the base substrate 200.

The buffer layer 205 may include, e.g., an inorganic insulating material such as, for example, silicon oxide, silicon nitride or silicon oxynitride. Embodiments of the present disclosure include using any of the materials alone or in a combination of two or more. In some embodiments, the buffer layer 205 may have a stacked structure including a silicon oxide layer and a silicon nitride layer.

The buffer layer 205 may be formed by a deposition process such as, for example, a chemical vapor deposition (CVD) process, a sputtering process, an atomic layer deposition (ALD) process, or the like, to include the inorganic insulating material.

The method may include disposing the transistors TR1, TR2 and TR3 on the buffer layer 205. A first transistor TR1, a second transistor TR2 and a third transistor TR3 may be electrically connected to a first light-emitting device ED1, a second light-emitting device ED2 and a third light-emitting device ED3, respectively.

Each of the transistors TR1, TR2 and TR3 may include an active layer 210, a gate insulation layer 220, a gate electrode 230, and connection electrodes 250 and 260. The transistors TR1, TR2 and TR3 may be electrically connected to the light-emitting devices of a first pixel area PX1, a second pixel area PX2 and a third pixel area PX3, respectively.

The active layer 210 may be disposed on the buffer layer 205, and may be patterned by, e.g., a photo-lithography process, such that the active layer 210 is repeatedly/regularly arranged at each pixel. The active layer 210 may include a silicon compound such as, for example, polysilicon or amorphous silicon. A p-type dopant or an n-type dopant may be doped in a partial region of the active layer 210, such that the active layer 210 may include a source region, a drain region, and a channel region.

The active layer 210 may include an oxide semiconductor such as, for example, indium gallium zinc oxide (IGZO), zinc tin oxide (ZTO) or ITZO.

The gate insulation layer 220 may be formed on the active layer 210, and the gate electrode 230 may be stacked on the gate insulation layer 220. As illustrated in FIG. 14, the gate insulation layer 220 may be formed in a pattern shape partially covering each active layer 210.

Alternatively, the gate insulation layer 220 may extend continuously over a plurality of pixel areas or light-emitting regions, and may be commonly included in the first to third transistors TR1, TR2 and TR3.

The gate electrode 230 may overlap the channel region of the active layer 210 in a thickness direction.

The gate insulation layer 220 may be formed by the described deposition process to include an inorganic insulating material such as, for example, silicon oxide, silicon nitride, silicon oxynitride, or the like. In some embodiments, the gate insulation layer 220 having a patterned shape may be formed as illustrated in FIG. 14 by the photo-lithography process in which the gate electrode 230 may substantially serve as an etching mask.

In some embodiments, the source region and the drain region may be formed in the active layer 210 by using the gate electrode 230 and the gate insulation layer 220 as an ion implantation mask.

An insulating interlayer 240 covering the gate insulation layer 220 and the gate electrode 230 may be formed on the active layer 210. The connection electrodes 250 and 260 which are in contact with or electrically connected to the active layer 210 may be formed on the insulating interlayer 240.

The insulating interlayer 240 may be formed by the described deposition process to include an inorganic insulating material such as, for example, silicon oxide, silicon nitride, silicon oxynitride, or the like. The insulating interlayer 240 may be formed in a single-layered structure or a multi-layered structure including different materials.

In some embodiments, when the active layer 210 includes an oxide semiconductor, hydrogen (H) contained in the insulating interlayer 240 may be diffused or transferred to the active layer 210 by a heat treatment process when forming the insulating interlayer 240. Accordingly, a carrier concentration may be increased by hydrogen, and thus the source region and the drain region having increased conductivity may be formed at lateral portions of the active layer 210.

The connection electrodes 250 and 260 may penetrate the insulating interlayer 240, and may be connected to the active layer 210. In an example in which the gate insulation layer 220 is continuously formed commonly in a plurality of the light-emitting regions, the connection electrodes 250 and 260 may also penetrate the gate insulation layer 220.

The connection electrode 250 may be a source electrode connected to or in contact with the source region of the active layer 210, and the connection electrode 260 may be a drain electrode connected to or in contact with the drain region of the active layer 210.

Contact holes may be formed by partially etching the insulating interlayer 240. For example, the contact holes exposing the source region and the drain region, respectively, may be formed. A metal layer sufficiently filling the contact holes may be formed on the insulating interlayer 240, and then the metal layer may be partially etched to form the connection electrode 250 (i.e., source electrode) and the connection electrode 260 (i.e., drain electrode).

The gate electrode 230 and the connection electrodes 250 and 260 may include a metal such as, for example, Ag, Mg, Al, W, Cu, Ni, Cr, Mo, Ti, Pt, Ta, Nd, Sc, the like or an alloy thereof, or nitrides thereof. The gate electrode 230 and the connection electrodes 250 and 260 may be formed by the above-mentioned deposition process described herein.

A planarization layer 270 covering the connection electrodes 250 and 260 may be formed on the insulating interlayer 240. The planarization layer 270 may accommodate a via structure electrically connecting the pixel electrode 280 and the connection electrode 260.

In some embodiments, the planarization layer 270 may include an organic material such as, for example, polyimide, an epoxy resin, an acrylic resin, polyester, a siloxane resin, a benzocyclobutene (BCB), or the like. The planarization layer 270 may be formed by the described deposition process or a spin coating process.

A pixel electrode 280 may be formed at each pixel such that the pixel electrode 280 is electrically connected to the transistors TR1, TR2 and TR3. The pixel electrode 280 may be formed on the planarization layer 270 such that the pixel electrode 280 is electrically connected to the connection electrode 260 (i.e., drain electrode).

For example, the planarization layer 270 may be partially etched to form a via hole exposing a top surface of the connection electrode 260 (i.e., drain electrode). A conductive layer including a metal material or a transparent conductive oxide and sufficiently filling the via hole may be formed on the top surface of the planarization layer 270, and then the conductive layer may be etched to form the pixel electrode 280.

The pixel electrode 280 may serve as an anode and may include a high work function conductive material that may promote a hole injection. The pixel electrode 280 may be provided as a transmissive electrode. The pixel electrode 280 may include a transparent conductive oxide such as, for example, indium tin oxide (ITO), indium zinc oxide (IZO), zinc oxide (ZnO), and indium tin oxide (ITZO).

The pixel electrode 280 may be provided as a transflective electrode or a reflective electrode. The pixel electrode 280 may include a metal selected from Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 280 may have a single-layered structure or a multi-layered structure. For example, the pixel electrode 280 may have a triple-layered structure of ITO/Ag/ITO.

A pixel defining layer PDL exposing a top surface of the pixel electrode 280 may be formed on the planarization layer 270. For example, the pixel area may be defined by a sidewall of the pixel defining layer PDL. For example, a green light-emitting region, a blue light-emitting region and a red light-emitting region may be separated and defined by the pixel defining layer PDL, and the light-emitting devices ED1, ED2 and ED3 may correspond to a blue light-emitting device, a red light-emitting device, and a green light-emitting device, respectively.

In some embodiments, all of the light-emitting devices ED1, ED2 and ED3 may be white light-emitting devices or blue light-emitting devices.

The pixel defining layer PDL may be formed by exposure and development processes after applying a photosensitive organic material such as, for example, a polysiloxane resin, a polyimide resin or an acrylic resin. In some embodiments, the pixel defining layer PDL may be formed by a printing process such as, for example, an inkjet printing process using a polymer material or an inorganic material.

In example embodiments, the pixel defining layer PDL or the pixel area may be formed by the exposure process using the described photomask.

A light-emitting portion may be disposed in each pixel area formed by the pixel defining layer PDL. In example embodiments, the light-emitting portion may include an emission layer EML including an organic light-emitting material. Accordingly, the display device may be provided as an organic light-emitting diode (OLED) device.

For example, the light-emitting portion may be formed by a process such as, for example, a vacuum deposition, a spin coating, an inkjet printing, a laser printing, a casting, a laser thermal transfer, or the like.

In some embodiments, a hole transport layer HTL may be disposed between the pixel electrode 280 and the emission layer EML. In some embodiments, the electron transport layer ETL may be disposed between the emission layer EML and a counter electrode 290.

The counter electrode 290 may be disposed on a top surface of the pixel defining layer PDL and the light-emitting portions. The counter electrode 290 may be a common electrode that may be continuously and commonly provided to a plurality of the light-emitting regions or the pixel areas.

The counter electrode 290 may serve as an electron injection electrode or a cathode. The counter electrode 290 may include a metal, an alloy, an electrically conductive compound, or the like, having a low work function.

For example, the counter electrode 290 may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, or the like. Embodiments of the present disclosure include using any of the materials alone or in a combination of two or more.

The counter electrode 290 may be provided as a transmissive electrode, a transflective electrode, or a reflective electrode. The counter electrode 290 may have a single-layered structure or a multi-layered structure.

The light-emitting devices ED1, ED2 and ED3 may be defined by the pixel electrode 280, the light emitting portion and the counter electrode 290 as described herein. The light-emitting devices ED1, ED2 and ED3 may be provided as organic light emitting diode (OLED) devices.

An encapsulation layer TFE may be formed on the counter electrode 290. The encapsulation layer TFE may be disposed on the pixel defining layer PDL and the light-emitting devices ED1, ED2 and ED3 to protect the light-emitting devices ED1, ED2 and ED3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, or the like), an epoxy resin (e.g., aliphatic glycidyl ether (AGE), or the like), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer and a second inorganic layer.

An optical structure or a sensor structure such as, for example, a polarizing plate, a touch sensor, a window substrate, or the like, may be further stacked on the encapsulation layer TFE to implement a display device.

FIG. 15 is a schematic partial enlarged plan view illustrating a pixel area of a display device according to embodiments.

Referring to FIG. 15, as described herein, the display device or the display panel DP may include first to third pixel areas PX1, PX2 and PX3. The first to third pixel areas PX1, PX2 and PX3 may be formed by the exposure process including the scan regions SCR in the scan direction SCD and the overlapping region OR shared by scan regions adjacent to each other in the sweeping direction SWD and using the described photomask PM.

At least one of the first to third pixel areas PX1, PX2, and PX3 may include a side having an oblique line shape inclined with respect to the sweeping direction SWD. For example, at least one of the first to third pixel areas PX1, PX2, and PX3 may have a rhombus shape.

In some embodiments, the first pixel area PX1 may have a rhombus shape, and the first pixel area PX1 may correspond to a blue pixel area or a blue light-emitting region.

As described herein, even when the first pixel area PX1 is formed in the overlapping region OR, the first pixel area PX1 having a desired shape/size may be formed by exposure conditions from which an error factor is corrected by using the monitoring mask pattern 150.

The arrangement of the pixel areas illustrated in FIG. 15 is provided as an example, and embodiments of the present disclosure include appropriately modifying the arrangement in consideration of light-emitting properties, a size, or other characteristics of the display device.

In some aspects, the exposure/etching process using the photomask PM according to the described embodiments may be used for a patterning process for the formation of patterns (the active layer 210, the gate electrode 230, the connection electrodes 250 and 260, or other patterns) included in the circuit layer CL or the transistors TR1, TR2 and TR3, and the pixel electrode 280.

The display device may be applied to various electronic devices such as, for example, a billboard, a guide signs, a light source/lighting, a personal computer such as, for example, a laptop computer or a desktop computer, a mobile phone, an electronic book, an electronic dictionary, an electronic notebook, various sensors including a diagnostic device, transportation means (automobile, aircraft, ship, train, or the like).

What is claimed is:

1. A photomask, comprising:
scan regions irradiated with unit beam areas in a scan direction;
an overlapping region comprising portions of adjacent scan regions among the scan regions, wherein the adjacent scan regions are adjacent in a sweeping direction of the scan regions and at least partially overlap, and the sweeping direction is perpendicular to the scan direction; and
a monitoring mask pattern that overlaps the overlapping region or is adjacent to a boundary of the overlapping region, wherein the monitoring mask pattern comprises a side having an oblique line shape inclined with respect to the sweeping direction.

2. The photomask of claim 1, wherein:
the monitoring mask pattern is provided in plurality, and
the plurality of monitoring mask patterns are arranged over the overlapping region in an inclined direction with respect to the scan direction.

3. The photomask of claim 1, wherein the monitoring mask pattern comprises a first monitoring mask pattern that is completely comprised within the overlapping region.

4. The photomask of claim 3, wherein the monitoring mask pattern further comprises:
a second monitoring mask pattern that overlaps an initiation line of the overlapping region; or
a third monitoring mask pattern that overlaps a terminal line of the overlapping region.

5. The photomask of claim 3, wherein:
the monitoring mask pattern further comprises a fourth monitoring mask pattern adjacent to an initiation line or a terminal line of the overlapping region, and
the fourth monitoring mask pattern is not arranged in the overlapping region.

6. The photomask of claim 1, wherein:
the monitoring mask pattern has a sloped angle with respect to the sweeping direction,
the monitoring mask pattern is provided in plurality, and
the plurality of monitoring mask patterns are arranged such that respective sloped angles of the plurality of monitoring mask patterns are different from one another.

7. The photomask of claim 6, wherein the sloped angle is adjusted in a range from 10° to 80°.

8. The photomask of claim 1, wherein:
the monitoring mask pattern is provided in plurality, and
the plurality of monitoring mask patterns have different respective sizes.

9. The photomask of claim 1, wherein:
the monitoring mask pattern is provided in plurality, and
the plurality of monitoring mask patterns comprise rhombus patterns having different ratios of lengths of two diagonal lines.

10. The photomask of claim 9, wherein the plurality of monitoring mask patterns further comprise a rectangular pattern sloped with respect to the sweeping direction.

11. The photomask of claim 1, wherein:
the photomask has a main area comprising a main mask pattern, a peripheral area at least partially surrounding the main area, and a monitoring mark area allocated in the peripheral area, and
the monitoring mask pattern is arranged in the monitoring mark area.

12. The photomask of claim 11, wherein:
the photomask comprises:
a transmissive layer; and
a mask pattern layer formed on the transmissive layer, and
the mask pattern layer comprises the monitoring mask pattern and the main mask pattern.

13. The photomask of claim 11, wherein:
the overlapping region is included in the monitoring mark area and the main area, and
the main mask pattern comprises a pattern having a side having an oblique line shape inclined with respect to the sweeping direction in the overlapping region.

14. The photomask of claim 1, wherein:
a width of the overlapping region in the sweeping direction ranges from 5 μm to 15 μm, and
a size of the monitoring mask pattern is less than a size of the overlapping region.

15. A method of fabricating a photomask, comprising:
forming a monitoring mask pattern by performing a preliminary exposure process, wherein the monitoring mask pattern comprises a side having an oblique line shape with respect to a sweeping direction, and the preliminary exposure process is performed such that adjacent scan regions extending in a scan direction share an overlapping region in a sweeping direction perpendicular to the scan direction;
comparing a size or a shape of the monitoring mask pattern with a size or a shape of a desired target mask pattern;
modifying exposure conditions based on a comparison result; and
forming a main mask pattern using the modified exposure conditions.

16. The method of claim 15, wherein:
the main mask pattern comprises a pattern comprising a side having an oblique line shape inclined with respect to the sweeping direction, and
the pattern is formed in the overlapping region by an exposure process.

17. The method of claim 15, wherein:
the monitoring mask pattern is respectively formed in monitoring mark areas,
the main mask pattern is formed in a main area, and
modifying the exposure conditions is performed repeatedly in multiple cycles based on comparison results in different monitoring mark areas before forming the main mask pattern.

18. A method for manufacturing a display device, comprising:
preparing a display panel comprising a base substrate, a circuit layer on the base substrate, pixel electrodes electrically connected to the circuit layer, and a pixel defining layer covering the pixel electrodes; and
forming pixel areas that expose the pixel electrodes by patterning the pixel defining layer using a photomask,
wherein the photomask comprises:
scan regions irradiated with unit beam areas in a scan direction;
an overlapping region comprising portions of adjacent scan regions comprised among the scan regions, wherein the adjacent scan regions are adjacent in a sweeping direction of the scan regions and at least partially overlap, and the sweeping direction is perpendicular to the scan direction; and
a monitoring mask pattern that overlaps the overlapping region or is adjacent to a boundary of the overlapping region, wherein the monitoring mask pattern comprises a side having an oblique line shape inclined with respect to the sweeping direction.

19. The method of claim 18, further comprising:
forming the photomask by a modified exposure process using the monitoring mask pattern,
wherein the photomask comprises main mask patterns, and each of the main mask patterns comprises a side having an oblique line shape inclined with respect to the sweeping direction.

20. The method of claim 19, wherein the pixel areas comprise a pixel area formed from an exposure process using a main mask pattern arranged in the overlapping region among the main mask patterns.
